(19) United States
(12) Patent Application Publication
(10) Pub. No.: US 2026/0018231 A1
(43) Pub. Date: Jan. 15, 2026

(54) MEMORY BUILT-IN SELF-TEST (MBIST) FOR A MEMORY EXPANSION OF A HIGH-BANDWIDTH MEMORY (HBM) DEVICE

(71) Applicant: Micron Technology, Inc., Boise, ID (US)

(72) Inventor: Sujeet Ayyapureddi, Boise, ID (US)

(21) Appl. No.: 19/261,806

(22) Filed: Jul. 7, 2025

Related U.S. Application Data
(60) Provisional application No. 63/669,058, filed on Jul. 9, 2024.

(51) Int. Cl. G11C 29/44

(52) U.S. Cl. CPC G11C 29/44

(57) ABSTRACT

This present invention relates to an HBM device with an MBIST engine. The HBM device includes a logic die and one or more memory dies. The logic die includes an HBM PHY configured to communicate signaling between a processor and the one or more memory dies, a separate die-to-die interface configured to communicate signaling between the processor and a memory controller, and the memory controller configured to communicate signaling between the die-to-die interface and one or more additional memory dies separate from the HBM device. The MBIST engine is also located on the logic die. The MBIST engine is coupled with the one or more memory dies and the memory controller and configured to operate a testing procedure on the one or more memory dies and the memory controller. In doing so, the MBIST engine can test the operability of the HBM device.

### CROSS-REFERENCE TO RELATED APPLICATION(S)

The present application claims priority to U.S. Provisional Patent Application No. 63/669,058, filed July 9, 2024, the disclosure of which is incorporated herein by reference in its entirety.

### TECHNICAL FIELD

The present disclosure generally relates to high-bandwidth memory (HBM) devices and, more particularly, relates to a memory built-in self-test (MBIST) for a memory expansion of an HBM device.

### BACKGROUND

Computing devices include a storage system that can be used to store data to be operated on by a processor. Increasingly complex applications for computing devices require storage systems that enable faster, less expensive, and more reliable computing. Storage systems often have a hierarchical architecture that can be used to store data closer to or farther from a processor. A processor can receive data from lower-level storage, which retrieves data from higher-level storage. For example, a hierarchical storage system can include, from the lowest level to the highest level, a cache memory, an HBM device, and an additional memory device (e.g., low-power double data rate 5 (LPDDR5) memory). In general, hierarchical layers implemented closer to the processor (e.g., lower levels) can be accessed more quickly but can have lesser capacities and be more costly to implement. Computing devices benefit from increasing the storage capacity at lower hierarchical levels; however, cost and spatial concerns can restrict such designs.

### BRIEF DESCRIPTION OF THE DRAWINGS

FIG. 1 illustrates an example schematic of a hierarchical storage architecture in accordance with an embodiment of the present technology.

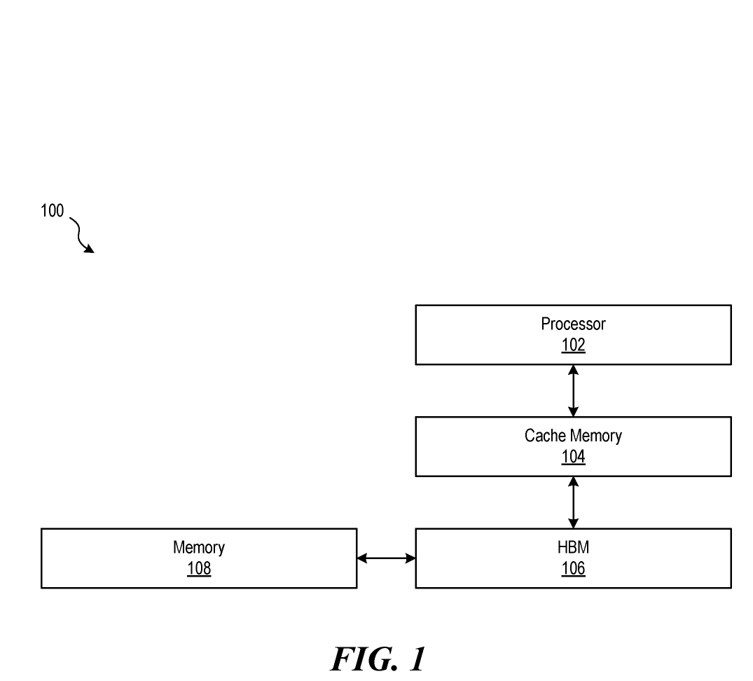

FIG. 2 illustrates an example computing device in which an HBM device in accordance with an embodiment of the present technology can operate.

FIG. 3 illustrates an example system-in-package (SiP) that includes a memory system in accordance with an embodiment of the present technology.

FIG. 4 illustrates a memory system with an MBIST engine in accordance with an embodiment of the present technology.

FIG. 5 illustrates an example method for operating an HBM device with an MBIST engine in accordance with an embodiment of the present technology.

### DETAILED DESCRIPTION

A computing device includes a storage system, which stores data to be operated on by a processor or other component of the host computing device. As applications for computing devices become more complex, storage systems are required to store greater amounts of data and communicate that data more quickly. To accomplish this, storage systems often include an HBM device capable of communicating data at an increased bandwidth through a high-bandwidth bus. HBM devices include an interface die that communicates signaling, using through-silicon vias (TSVs), to one or more memory dies stacked on the interface die. The interface die can implement logical circuitry used for communicating with or testing the memory dies. For example, the interface die can implement a physical layer (PHY) used to communicate signaling between the HBM device and other devices (e.g., a host device). The interface die can further implement an MBIST engine used to test the operability of the memory dies or other components of the HBM device (e.g., the PHY). By providing multiple memory dies through a vertically integrated device accessible through a high-bandwidth bus, HBM devices provide greater amounts of storage, accessed more efficiently, within a smaller form factor. With this improved functionality, however, can come increased cost or complexity.

To increase the storage capacity of storage systems efficiently and cost- effectively, storage systems may implement additional storage devices arranged in a hierarchical structure where data is stored closer to or further from the processor. For example, illustrates a hierarchical storage architecture 100 in accordance with an embodiment of the present technology where a processor 102 accesses data from a cache memory 104, an HBM 106, and additional memory 108.

The cache memory 104 can store small amounts of data close to the processor 102 such that this data can be accessed with low latency. In some cases, the cache memory can include a high-speed, random-access memory (RAM), such as static RAM (SRAM). The cache memory 104 can include a single-level cache or a multilevel cache (e.g., a L1 cache, a L2 cache, etc.). In embodiments, the single-level cache and/or one or more levels of the multilevel cache may be part of the die of processor 102. Given that the cache memory 104 is located close to the processor 102 and communicates with low latency, communication efficiency is improved when the data requested by the processor 102 is stored in the cache memory 104 (e.g., a cache hit). If the requested data is not in the cache memory 104 (e.g., a cache miss), this data can be retrieved from the HBM 106 or the additional memory 108 and stored in the cache memory 104 from which the data can be accessed by the processor 102.

The HBM 106 can store a larger amount of data than the cache memory 104, though this data may be returned with higher latency. For example, the HBM 106 can include 8, 16, 24, or 48 GB, or any other amount of a volatile memory, such as dynamic RAM (DRAM). Data can be stored in the HBM 106 to be retrieved and stored in the cache memory 104. When the requested data is not located in the cache memory 104 or the HBM 106, the data can be retrieved from the additional memory 108. In this way, the additional memory devices can act as a memory expansion of the HBM 106. The additional memory 108 can include one or more higher-latency, lower-bandwidth memory devices. For example, the additional memory 108 can include multiple volatile memory devices (e.g., DRAM devices, such as LPDDR5 devices) having 8, 16, 24, 32, or 48 GB, or any other amount of volatile memory. When data is retrieved from additional memory 108, it can sometimes be stored in the HBM 106 such that subsequent requests to access the data can be retrieved directly from the HBM 106 without having to access the additional memory 108, which can improve latency. When space is needed in the HBM 106 to store newly requested data, previously requested data can be overwritten.

Although not illustrated, the storage system can further include a high-latency, large-capacity storage device (e.g., non-volatile memory). For example, the storage device can include NOT-AND (NAND) Flash storage having a capacity of 500 GB, 1 TB, 2 TB, and so on. When data is retrieved from the storage device, it can be stored in the HBM 106 or the additional memory 108 to improve latency in subsequent requests for the data.

The HBM 106 and the processor 102 (e.g., through the cache memory 104) can be connected through a high-bandwidth interconnect, which can include any number of buses, implemented on a substrate (e.g., an interposer or printed circuit board (PCB)). The HBM 106 can include an HBM PHY that enables communication along the high-bandwidth interconnect in accordance with an HBM specification (e.g., HBM3, HBM4, or any other past or future generations of the HBM specification). Thus, data can be communicated between the HBM 106 and the processor 102 with a high bandwidth (e.g., >1 TB/s).

The additional memory 108 is also connected with the processor 102 through an interconnect. The addition of the additional memory 108 can create spatial concerns, however. Not only must the substrate have space to implement the additional storage devices themselves but also the components for testing (e.g., an MBIST engine) and communicating with (e.g., a PHY or memory controller) these additional storage devices. Moreover, given the width of the high-bandwidth interconnect and crowding from other circuitry implemented on the substrate, there may be insufficient room to implement a direct interconnect between the processor 102 and the additional memory 108 on the substrate. Accordingly, additional techniques are needed to implement spatially efficient testing and routing schemes within a storage system.

To overcome these challenges and others, the disclosed technology relates to an HBM device that can be used to implement an interconnect between a processor and one or more additional memory devices. In doing so, much of the routing circuitry can be moved off of the substrate and onto the HBM device to enable the additional memory devices to be implemented even on substrates with high routing density. For example, the interface die of the HBM device can include an HBM PHY used for communications between the processor and the memory dies of the HBM device and a standard compliant PHY (e.g., a Peripheral Component Interconnect Express (PCle) PHY, Universal Chiplet Interconnect Express (UCle) PHY, Compute Express Link (CXL) PHY, or any other communication standard compliant interface) for communications between the processor and the additional memory devices. The interface die of the HBM device can further include one or more memory controllers coupled with the standard complaint PHY and capable of managing communications with the additional memory devices. In this way, the memory controllers can be moved off of the host device and onto the HBM device.

The interface die of the HBM device can further include an MBIST engine configured to test the operability of the HBM device. For example, the MBIST engine can communicate test sequences to the memory dies (through the TSVs) or the HBM PHY to determine the operability of the memory dies or the HBM PHY. Given that the standard compliant PHY and the memory controllers are also located on the interface die of the HBM device, the MBIST engine can also be used to test the operability of the standard compliant PHY and the memory controller (and, through extension, the additional memory devices). For example, the MBIST engine can communicate test sequences to the standard compliant PHY and the memory controller to test the operability of these components (and the additional memory devices through the memory controller). In this way, the additional memory devices and the components located on the HBM device can be tested with a single MBIST engine, thereby reducing device size and improving efficiency.

Various aspects of an MBIST engine for a memory expansion of an HBM device will be described with reference to Figures2-5.

### Example Operating Environment

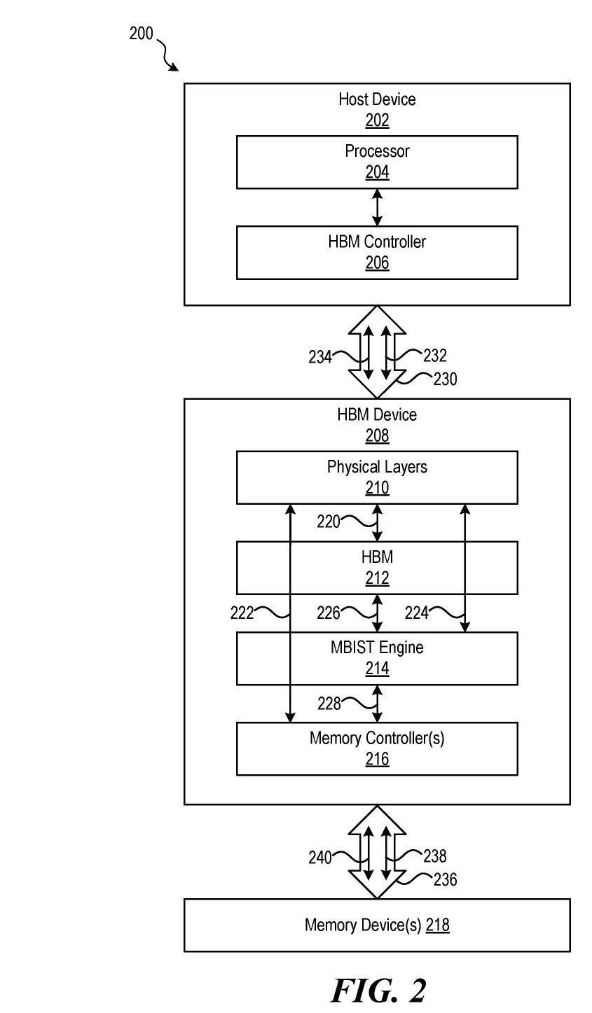

FIG. 2 illustrates an example computing device 200 in which an HBM device 208 in accordance with an embodiment of the present technology can operate. The computing device 200 includes a host device 202, an HBM device 208, and one or more additional memory devices 218. The host device 202 includes at least one processor 204 and at least one HBM controller 206. The HBM device 208 includes one or more PHYs 210 (e.g., an HBM PHY and one or more standard compliant PHYs), HBM 212, an MBIST engine 214, and one or more memory controllers 216. The one or more memory devices 218 can be any type of memory device (e.g., a DRAM device, such as an LPDDR5 device). In aspects, the memory devices 218 can communicate at a lower bandwidth than the HBM device 208. Thus, in some instances, the memory devices 218 can be referred to as low- bandwidth memory.

The host device 202 can initiate read/write requests to the HBM device 208. The HBM controller 206 can include control logic that is capable of issuing commands to the HBM device 208 through the PHYs 210 (e.g., the HBM PHY). The HBM controller 206 can manage any aspects of the commands. For example, the HBM controller 206 can handle scheduling, addressing, wear leveling, refresh, and so on. After issuing the commands, the HBM controller 206 can receive data from the HBM device 208 through the PHYs 210. Once again, the HBM controller 206 can manage any operations on the returned data, for example, error correction. In some examples, HBM controller 206 may be an aspect of, and may reside on or within, the processor 204.

Although not illustrated in FIG. 2, the host device 202 can include some control logic capable of issuing commands to access the memory devices 218. Given that the memory devices 218 are coupled with the host device 202 through the HBM device 208, these commands can be transmitted to the HBM device 208 to be sent to the memory devices 218. In aspects, the control logic communicates with the HBM device 208 through the PHYs (e.g., the one or more standard compliant PHYs). While the control logic is capable of issuing commands, this control logic can lack much of the functionality provided by a memory controller. Instead, these functionalities will be offloaded to the memory controllers 216 residing on the HBM device 208. Accordingly, the control logic can be, for example, a simple scheduler capable of issuing commands.

The HBM device 208 can include control logic (e.g., located on an interface die of the HBM device 208) that is capable of receiving the commands from the host device 202 (e.g., through the HBM PHY) and issuing commands to the HBM 212. In response to the commands, the HBM 212 can write to memory, return data to memory, or perform any other operation. This data can be returned to the host device 202. The control logic is similarly capable of receiving commands to access the memory devices 218 and communicating these commands to the memory controllers 216. The memory controllers 216 can receive the commands and, based on them, issue commands to the memory devices 218 to perform one or more operations (e.g., read, write, and so on). Like the HBM controller 206, the memory controller 216 can perform other operations related to managing memory, signaling, and data returns (e.g., scheduling, addressing, wear leveling, refresh, error correction, and so on). Data returned from the memory devices 218 can be received by the memory controllers 216 and returned to the host device 202. In aspects, commands directed to the HBM device 208 are received through the PHYs 210 (e.g., commands directed to the HBM 212 are received through the HBM PHY and commands directed to the memory devices 218 are received through the standard compliant PHYs). Data is similarly returned from the HBM device 208 to the host device 202 through the PHYs 210.

In aspects, the components of the HBM device 208 can be coupled with TSVs and routing circuitry. For example, the PHYs 210 can connect to the HBM 212 through circuitry 220 (e.g., traces, lines, vias, TSVs, and other connective circuitry) and the memory controllers 216 through circuitry 222 (e.g., traces, lines, vias, and other connective circuitry). In aspects, the HBM PHY couples with the HBM 212, and the standard compliant PHYs couple with the memory controllers 216.

An MBIST engine 214 is also coupled with the various components of the HBM device 208 through circuitry to enable the MBIST engine 214 to determine the operability of the various components of HBM device 208. The MBIST engine 214 can provide self-testing and self-repair functionality to the HBM device 208. For example, the MBIST engine 214 can run various sequences through the PHYs 210, the HBM 212, and the memory controllers 216 to test the components for faults. The MBIST engine 214 can independently test the HBM device 208 (e.g., entirely independently or in response to initiation from the host device 202). For example, the MBIST engine 214 can independently generate test sequences and apply them to the components of the HBM device 208. The MBIST engine 214 can then compare the expected output with the actual output to detect any faults. In some cases, the MBIST engine 214 can automatically repair faults. For example, the MBIST engine 214 can identify faulty memory cells and replace them with redundant cells, ensuring the functionality of the HBM device 208 is maintained.

The MBIST engine 214 can couple with the PHYs 210 through the circuitry 224 (e.g., traces, lines, vias, and other connective circuitry), the HBM 212 through circuitry 226 (e.g., traces, lines, vias, TSVs, and other connective circuitry), and the memory controllers 216 through circuitry 228 (e.g., traces, lines, vias, and other connective circuitry). Given that the MBIST engine 214 is coupled with the various components of the HBM device 208, the MBIST engine 214 can test the operability of the PHYs 210, the HBM 212, the memory controllers 216, and, through the memory controllers 216, the memory devices 218. Although not illustrated, the MBIST engine 214 can further couple with any additional intellectual property (IP) on the HBM device 208 for testing the IP. For example, the MBIST engine 214 can couple with additional memory controllers for controlling additional memory, additional storage controllers (e.g., Flash controllers) for controlling attached storage devices, error correction IP, and so on.

In aspects, the MBIST engine 214 can maintain separate data paths or partially shared data paths for testing the components of the HBM device 208. If the data paths are partially shared, the data paths can include control logic for directing signaling to particular components. For example, the shared data paths can include multiplexers or other logical circuitry that can direct signaling in a particular direction based on state changes (e.g., initiated by the MBIST engine 214 or the host device 202) to the multiplexers. In aspects, some components may be accessed individually or through other components. For example, in some embodiments, the HBM 212 may be accessible only through the PHYs 210 (e.g., the HBM PHY) or the memory controllers 216 may be accessible only through the PHYs 210 (e.g., the standard compliant PHYs). In other cases, the HBM 212 or the memory controllers 216 can be accessible directly by the MBIST engine 214.

Although the MBIST engine 214 is self-contained and operable independently, in some embodiments, the MBIST engine 214 can receive specific sequences from the host device 202 with which to test the components of the HBM device 208. For example, the host device 202 can directly access the MBIST engine 214 through the PHYs 210 or a separate interface (e.g., an IEEE 1500 interface or other interface) and provide specific sequences for the MBIST engine 214 to use in the testing procedure. The MBIST engine 214 can then run this sequence through one or more components of the HBM device 208 (e.g., at the direction of the host device 202 or independently).

The computing device 200 further includes an interconnect 230 coupled between the host device 202 and the HBM device 208, with command-address (CA) buses 232 and one or more data (DQ) buses 234, and an interconnect 236 coupled between the HBM device 208 and the memory devices 218, with CA buses 238 and DQ buses 240. In aspects, the interconnect 230 can be wider and support a larger bandwidth than the interconnect 236. The computing device 200 can be any type of computing device, computing equipment, computing system, or electronic device, for example, hand-held devices (e.g., mobile phones, tablets, digital readers, and digital audio players), computers, vehicles, or appliances. Components of the computing device 200 may be housed in a single unit or distributed over multiple, interconnected units (e.g., through wired or wireless interconnects). In aspects, the host device 202, the HBM device 208, and the additional memory devices 218 are discrete components mounted to and electrically coupled through an interposer, PCB, or other organic or inorganic substrate (e.g., implementing a portion of the interconnect 230 and the interconnect 236).

As shown, the host device 202 and the HBM device 208 are coupled with one another through the interconnect 230. The processor 204 executes instructions that cause the HBM controller 206 of the host device 202 to send signals on the interconnect 230 that control operations at the HBM device 208. The processor 204 similarly executes instructions that cause control circuitry (not shown) at the host device 202 to send signals on the interconnect 230 that control operations at the memory devices 218 through excitation of the memory controllers 216. The HBM device 208 can similarly communicate data (e.g., from the HBM 212 or the memory devices 218) to the host device 202 over the interconnect 230. The CA buses 232 can communicate control signaling (e.g., through CA pins in the PHYs 210) indicative of commands to be performed at select locations (e.g., addresses within the HBM 212 or at the memory controllers 216) of the HBM device 208. The DQ buses 234 can communicate data between the host device 202 and the HBM device 208. For example, the DQ buses 234 can be used to communicate data (e.g., through DQ pins in the PHYs 210) to be stored in the HBM device 208 in accordance with a write request, data retrieved from HBM device 208 in accordance with a read request, or an acknowledgment returned from the HBM device 208 in response to successfully performing operations at the HBM device 208. The CA buses 232 can be realized using a group of wires, vias, or other circuit components, and the DQ buses 234 can encompass a different group of wires, vias, or other circuit components of the interconnect 230. As some examples, the interconnect 230 can include a front-side bus, a memory bus, an internal bus, a peripheral control interface (PCI) bus, a high-bandwidth bus, etc.

The interconnect 236 can provide similar communication between the HBM device 208 and the memory devices 218. For example, the CA buses 238 can transmit control signaling between the memory controllers 216 and the memory devices 218, and the DQ buses 240 can transmit data between the memory controllers 216 and the memory devices 218.

The processor 204 can read from and write to the HBM device 208 (e.g., through the HBM controller 206) and the memory devices 218 (e.g., through communications with the HBM device 208). The processor 204 may include the computing device's host processor, central processing unit (CPU), graphics processing unit (GPU), artificial intelligence (AI) processor (e.g., a neural-network accelerator), or other hardware processor or processing unit.

The HBM device 208 can include any HBM 212, such as integrated circuit memory, dynamic memory, or RAM (e.g., DRAM or SRAM), to name just a few. The HBM device 208 can further include any amount of HBM 212 (e.g., 8 GB, 16 GB, 32 GB, or 64 GB). In aspects, the HBM 212 includes volatile memory. The HBM device 208 can include HBM 212 of a single type or HBM 212 of multiple types. In general, the HBM device 208 can be implemented as any addressable memory having identifiable locations of physical storage. The HBM device 208 can include the memory-side memory controller (not shown), which executes commands from the HBM controller 206. For example, the memory-side memory controller can decode signals from the HBM controller 206 and issue commands to cause operations to be performed at the HBM 212. Commands can be issued along internal CA buses, and data can be returned along DQ buses. The CA buses or DQ buses can be implemented using TSVs and other circuitry (e.g., circuitry 220).

The memory devices 218 can similarly include any memory (e.g., of one or more types) and any amount of memory. In aspects, the memory devices 218 include volatile memory. The memory devices 218 can be implemented as any addressable memory having identifiable locations of physical storage. The memory devices 218 can similarly include a memory-side memory controller (not shown), which executes commands from the memory controllers 216. The memory devices 218 can function to increase the memory capacity of the computing device 200. For example, data that is written to or flushed from the HBM device 208 can be stored in the memory devices 218. Once flushed from HBM device 208, it can be loaded back to the HBM device 208 when requested. In other cases, the memory devices 218 can function as separate memory that is accessible to the host device without being stored within the HBM 212 of the HBM device 208. In this way, the HBM device 208 can act only as a facilitator of communications between the host device 202 and the memory devices 218.

### Example System-in-Package (SiP)

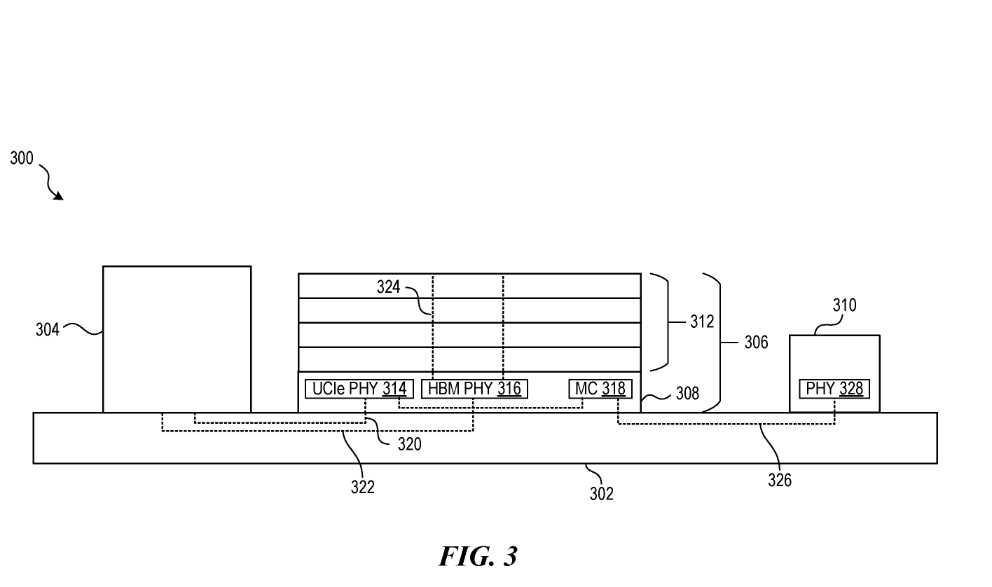

FIG. 3 illustrates an example system-in-package (SiP) 300 that includes a memory system in accordance with an embodiment of the present technology. As illustrated in FIG. 3, the SiP 300 includes a base substrate 302 (e.g., a silicon interposer, a PCB, an organic or inorganic substrate, and/or the like) as well as a CPU/GPU 304 (e.g., an example of host device 202 illustrated in FIG. 2), the HBM device 306 (e.g., an example of the HBM device 208 illustrated in FIG. 2), and one or more memory devices 308, each integrated at an upper surface of the base substrate 302. In the illustrated embodiment, the CPU/GPU 304, and associated components (e.g., the register, L1 cache, and the like), is illustrated as a single package, the HBM device 306 includes a stack of semiconductor dies, and the memory devices 308 include separated memory devices.

The stack of semiconductor dies in the HBM device 306 includes an interface die 308 and one or more memory dies 312 (four illustrated in FIGURE3) (e.g., an example of the HBM 212 illustrated in FIGURE2). The interface die 308 includes a UCIe PHY 314 and an HBM PHY 316 (e.g., examples of the PHYs 210 illustrated in FIGURE2) and memory controllers 318 (e.g., examples of the memory controllers 216 in FIGURE2). Although illustrated as a UCIe PHY, the UCIe PHY 314 could instead be replaced with any die-to-die interface, such as any other standard compliant PHY.

The CPU/GPU 304 is coupled to the HBM device 306 through a high-bandwidth bus that includes route lines 320 and route lines 322 formed into (or on) the base substrate 302. As illustrated, the route lines 320 couple the CPU/GPU 304 with the UCIe PHY 314, and the route lines 322 couple the CPU/GPU 304 (e.g., through an HBM memory controller (not shown)) with the HBM PHY 316. In various embodiments, the route lines 320 and route lines 322 can include one or more metallization layers formed in one or more redistribution layers (RDLs) of the base substrate 302 and/or one or more vias interconnecting the metallization layers and/or traces. Further, although not illustrated in FIG. 3, it will be understood that the CPU/GPU 304 and the HBM device 306 can each be coupled to the route lines 320 and the route lines 322 via solder structures (e.g., solder balls), metal-metal bonds, wiring, and/or any other suitable conductive couplings. That is, the high-bandwidth bus of the base substrate 302 can couple the CPU/GPU 304 to the HBM device 306, and any buses therein (e.g., an internal high-bandwidth bus within the HBM device 306). The internal high-bandwidth bus of the HBM device 306 can include a plurality of TSVs 324 extending from the interface die 308 to the memory dies 312.

The HBM device 306 is coupled to the memory devices 310 through a bus that includes route lines 326 formed into (or on) the base substrate 302. This bus can be configured similarly to the high-bandwidth bus between the CPU/GPU 304 and the HBM device 306, albeit with a lower bandwidth. As illustrated, the route lines 326 couple the memory controllers 318 with PHYs 328 located on the memory devices 310. The PHYs 328 can be configured in accordance with any die-to-die interface protocol, such as any standard compliant protocol. Although not illustrated in FIGURE3, it will be understood that the HBM device 306 and the memory devices 310 can each be coupled to the route lines 326 via solder structures (e.g., solder balls), metal-metal bonds, wiring, and/or any other suitable conductive couplings. In aspects, the memory devices 310 can be LPDDR5 memory devices, or any other type of memory device. Moreover, the memory devices 310 can be memory devices of the same type or of different types. Each of the memory devices 310 can be implemented as a single die, multiple dies spaced horizontally, or as a stack of dies.

Given that the CPU/GPU 304 does not couple directly with the memory devices 310, the CPU/GPU 304 may only be able to access the memory devices 310 through the HBM device 306. Moreover, given that route lines are not needed to extend entirely from the CPU/GPU 304 to the memory devices 310 through the base substrate 302, routing density on the base substrate can be reduced.

Once the HBM device 306 and the memory devices 310 are packaged into individual devices, some IP on these devices may lack external access (e.g., memory dies 312 or the memory controller 318 within the HBM device 306 or memory within the memory devices 310). Once the HBM device 306 and the memory devices 310 are packaged onto the base substrate 302, this external access becomes even more limited. Nonfunctional IP can render large portions of the SiP 300, or a larger computing device in which the SiP 300 is integrated, inoperable or inefficient. Accordingly, testing the various IP within the various components of the SiP 300, even those that lack external access, can improve yield and reduce cost. To enable this testing, an MBIST engine can be used.

### Example Memory System with an MBIST Engine

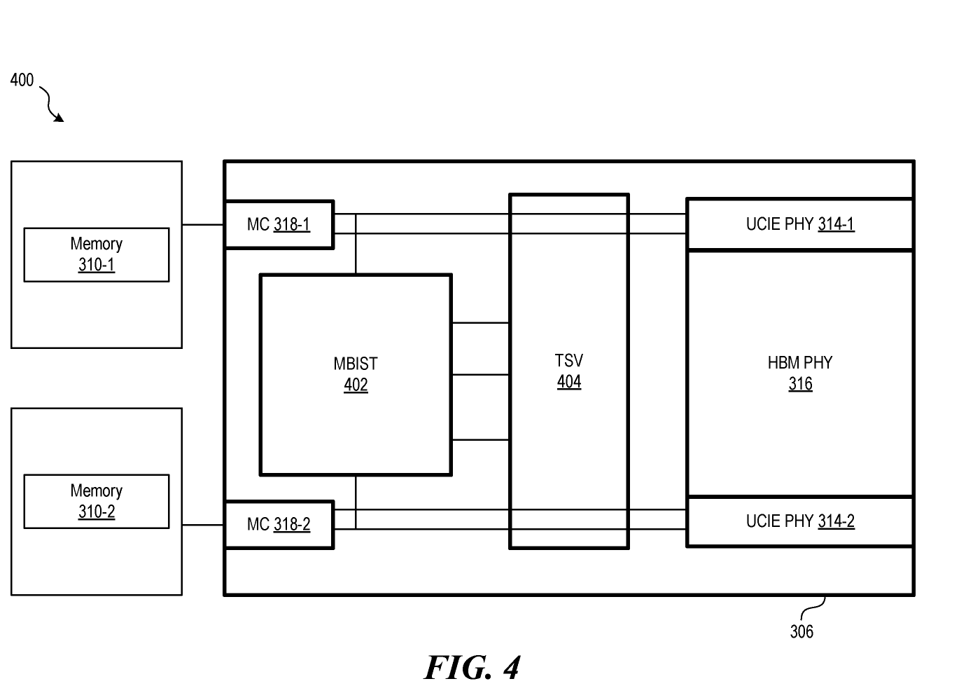

FIG. 4 illustrates an example memory system 400 with an MBIST engine 402 in accordance with an embodiment of the present technology. The memory system 400 includes a schematic of an interface die of an HBM device 306 on which the MBIST engine 402 is implemented. The HBM device 306 includes UCIe PHYs 314 coupled with memory controllers 318 (e.g., UCIe PHY 314-1 coupled with memory controller 318-1 and UCIe PHY 314-2 coupled with memory controller 318-2) operable to control the memory devices 310 (e.g., memory controller 318-1 controls memory device 310-1 and memory controller 318-2 controls memory device 310-2). Although illustrated as UCIe PHYs 314, the HBM device 306 could alternatively or additionally implement any other die-to-die interface, such as a different standard compliant PHY. The HBM device 306 further includes HBM PHY 316 coupled with TSVs 404 that connect to memory of the HBM device 306. In this way, the HBM PHY 316 can be used to transmit/receive signaling to/from the memory of the HBM device 306.

The example memory system 400 includes memory devices 310 that increase the memory capacity of the memory system 400. Although illustrated as two memory devices, the memory devices 310 can include any number of memory devices. The memory controllers 318 and the UCIe PHYs 314 can similarly include any number of memory controllers and PHYs, respectively, such that there is one memory controller and one UCIe PHY for each of the memory devices 310. In other cases, one or more of the memory controllers 318 or the UCIe PHYs 314 can be coupled with multiple memory devices, or vice versa.

The MBIST engine 402 is coupled with the various components of the HBM device 306 through circuitry to enable the MBIST engine 402 to test the operability of the various components. The MBIST engine 402 can provide self-testing and self-repair functionality to the HBM device 306. For example, the MBIST engine 402 can run various sequences through the UCIe PHYs 314, the memory controllers 318, or, through extension, the memory devices 310 to test for faults in the memory devices 310 or their path back to the host device. Similarly, the MBIST engine 402 can run sequences through the HBM PHY 316, the TSVs 404, or the HBM within the HBM device 306 to test for faults in the HBM or the data path for receiving data from the HBM device 306. The MBIST engine 402 can independently test the HBM device 306 (e.g., entirely independently or in response to initiation from the host device 202). For example, the MBIST engine 402 can independently generate test sequences and apply them to the components of the HBM device 306. The MBIST engine 402 can then compare the expected output with the actual output to detect any faults. In some cases, the MBIST engine 402 can automatically repair faults. For example, the MBIST engine 402 can identify faulty memory cells and replace them with redundant cells, ensuring that the functionality of the HBM device 306 is maintained.

Although not illustrated, the MBIST engine 402 can further couple with any additional IP on the HBM device 306 for testing the IP. For example, the MBIST engine 402 can couple with additional memory controllers for controlling additional memory, additional storage controllers for controlling attached storage devices (e.g., Flash controllers), error correction IP, and so on. In this way, the HBM device 306 can test the functionality to the UCIe PHYs 314, the memory controllers 318, the memory devices 310, and any additional IP using the MBIST engine 402 without requiring additional testing engines.

The MBIST engine 402 can maintain separate data paths or partially shared data paths for testing the components of the HBM device 306. If the data paths are partially shared, the data paths can include control logic for directing signaling to particular components. For example, the shared data paths can include multiplexers or other logical circuitry that can direct signaling in a particular direction based on state changes (e.g., initiated by the MBIST engine 402) to the multiplexers. In some embodiments, the UCIe PHYs 314, the memory controllers 318, or the memory devices 310 can be accessed in a first state, and the HBM PHY 316, the TSVs 404, or the HBM can be accessed in a second state.

Although the MBIST engine 402 is self-contained and operable independently, in some embodiments, the MBIST engine 402 can receive specific sequences from the host device with which to test the components of the HBM device 306. For example, the host device can directly access the MBIST engine 402 through any available interface (e.g., an Institute of Electrical and Electronics Engineers (IEEE) 1500 interface or other interface (not shown)) and provide specific sequences for the MBIST engine 402 to test. The MBIST engine 402 can then run this sequence through one or more components of the HBM device 306 (e.g., at the direction of the host device) and compare the output to an expected output to detect faults.

### Example Method for Operating a Memory Device

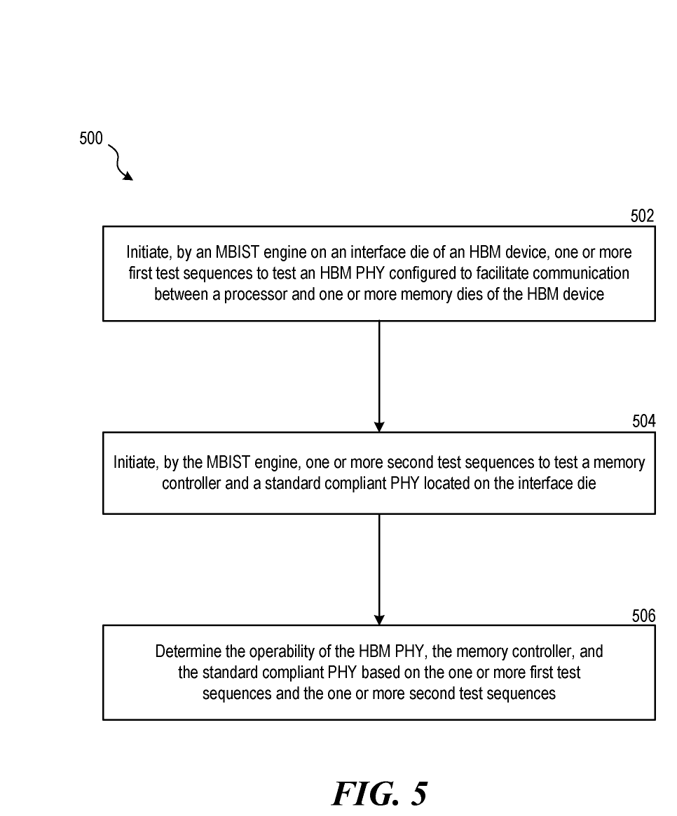

FIG. 5 illustrates an example method 500 for operating an HBM device with an MBIST engine in accordance with an embodiment of the present technology. Although illustrated in a particular configuration, one or more operations of the method 500 may be omitted, repeated, or reorganized. Additionally, the method 500 may include other operations not illustrated in FIG. 5, for example, operations detailed in one or more other methods described herein. The operations described herein may be implemented in hardware, software executed by a processor, firmware, or any combination thereof. For instance, the operations can be performed by an MBIST engine located on an HBM device.

At 502, one or more first test sequences to test an HBM physical layer (PHY) configured to facilitate communication between a processor and one or more memory dies of the HBM device are initiated. The first test sequences can be initiated by an MBIST engine on an interface die of an HBM device. In some embodiments, the MBIST engine can direct the first test sequences to the HBM PHY by configuring control logic (e.g., multiplexers) at a data path between the MBIST engine and the memory controller, the HBM PHY, and the standard compliant PHY (or other die-to-die interface) to be in a first state.

At 504, one or more second test sequences to test a memory controller or a standard compliant PHY (e.g., a UCIe PHY) located on the interface die are initiated. The memory controller can be configured to communicate signaling to one or more additional memory dies separate from the HBM device. The additional memory dies can implement one or more memory devices, and the memory controllers can be configured to comport with a standard for communication with the memory devices. For example, the additional memory dies can implement LPDDR5 memory devices, and the memory controllers can include LPDDR5 memory controllers that comply with the LPDDR5 specification. The standard compliant PHY can be configured to facilitate communication between the processor and the memory controller.

In some embodiments, the MBIST engine can receive from the processor one or more third test sequences to test at least one of: the HBM PHY, the memory controller and the standard compliant PHY. In response to receiving the one or more third test sequences, the MBIST engine can initiate the one or more third test sequences to test the HBM PHY, the memory controller (e.g., through the standard compliant PHY), or the standard compliant PHY.

At 506, the MBIST engine can determine the operability of the HBM PHY, the memory controller, and the standard compliant PHY based on the one or more first test sequences and the one or more second test sequences (and, in some cases, the one or more third test sequences). For example, the MBIST engine can compare the output from the components in response to the test sequences to expected outputs. If the outputs match the expected outputs, the components can be deemed operable. If the outputs do not match the expected outputs, the components can be deemed inoperable or to have faults. In some cases, the MBIST engine can identify the specific components that are causing the faults and report the faults, for example, to a host device or other error recording system. In yet other cases, the MBIST engine can identify the specific components that are causing the faults and repair them.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word "or" is expressly limited to mean only a single item exclusive from the other items in reference to a list of two or more items, then the use of "or" in such a list is to be interpreted as including (a) any single item in the list, (b) all of the items in the list, or (c) any combination of the items in the list. Furthermore, as used herein, the phrase "and/or" as in "A and/or B" refers to A alone, B alone, and both A and B. Additionally, the terms "comprising," "including," "having," and "with" are used throughout to mean including at least the recited feature(s) such that any greater number of the same features and/or additional types of other features are not precluded. Further, the terms "generally", "approximately," and "about" are used herein to mean at least within 10 percent of a given value or limit. Purely by way of example, an approximate ratio means within 10 percent of the given ratio.

Several implementations of the disclosed technology are described above in reference to the figures. The computing devices on which the described technology may be implemented can include one or more CPUs, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Thus, computer-readable media can comprise computer-readable storage media (e.g., "non-transitory" media) and computer-readable transmission media.

It will also be appreciated that various modifications may be made without deviating from the disclosure or the technology. For example, the dies in the described memory device (e.g., the HBM device or the additional memory devices) can be arranged in any other suitable order. Further, one of ordinary skill in the art will understand that various components of the technology can be further divided into subcomponents or that various components and functions of the technology may be combined and integrated. In addition, certain aspects of the technology described in the context of particular embodiments may also be combined or eliminated in other embodiments. For example, although discussed herein as using a volatile memory (e.g., DRAM devices, such as LPDDR5 devices) to expand the memory of the HBM device, it will be understood that alternative memory extension dies can be used (e.g., non-volatile memory, larger-capacity DRAM dies, other volatile memory devices (e.g., compliant with other standards, such as other versions of the LPDDR standard), and/or any other suitable memory component). While such embodiments may forgo certain benefits (e.g., volatile storage), such embodiments may nevertheless provide additional benefits (e.g., reduce routing density, allowing many complex computation operations to be executed relatively quickly, etc.).

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A high-bandwidth memory (HBM) device comprising:
one or more memory dies; and
a logic die on which the one or more memory dies are assembled, the one or more memory dies comprising: an HBM physical layer (PHY) configured to communicate signaling between a processor and the one or more memory dies; a communication standard compliant PHY configured to communicate signaling between the processor and a memory controller; the memory controller configured to communicate signaling between the communication standard compliant PHY and one or more additional memory dies separate from the HBM device; and a memory built-in self-test (MBIST) coupled with the one or more memory dies and the memory controller and configured to operate a testing procedure on the one or more memory dies and the memory controller.

2. The HBM device of claim 1, wherein the MBIST is coupled with the HBM PHY and configured to operate the testing procedure on the HBM PHY.

3. The HBM device of claim 1, wherein the MBIST is coupled with the communication standard compliant PHY and configured to operate the testing procedure on the communication standard compliant PHY.

4. The HBM device of claim 1, wherein the memory controller communicates with the additional memory dies at a lower bandwidth than the HBM device.

5. The HBM device of claim 1, wherein the MBIST is coupled with the one or more memory dies and the memory controller through control logic, wherein the control logic
Client Ref. Nos. 2023147814-US-2 enables the MBIST to operate the testing procedure on the one or more memory dies in a first state and operate the testing procedure on the memory controller in a second state.

6. The HBM device of claim 1, wherein the memory controller is compliant with a Low-Power Double Data Rate (LPDDR) 5 standard.

7. The HBM device of claim 1, wherein the communication standard compliant PHY is compliant with a Universal Chiplet Interconnect Express (UCIe) standard.

8. The HBM device of claim 1, wherein:
the MBIST is configured to receive one or more test sequences from the processor; and the one or more test sequences are included within the testing procedure.

9. A semiconductor device comprising:
a substrate;
a processor assembled onto the substrate;
a high-bandwidth memory (HBM) device assembled onto the substrate, the HBM device comprising: one or more memory dies; and a logic die on which the one or more memory dies are assembled, the one or more memory dies comprising: an HBM physical layer (PHY) coupled with the processor and the one or more memory dies; a die-to-die interface separate from the HBM PHY and coupled with the processor and a memory controller; the memory controller coupled with the die-to-die interface and one or more additional memory dies; and a memory built-in self-test (MBIST) coupled with the one or more memory dies and the memory controller and configured to
operate a testing procedure on the one or more memory dies and the memory controller; and
the one or more additional memory dies assembled onto the substrate.

10. The semiconductor device of claim 9, wherein:
the MBIST is coupled with the HBM PHY and configured to operate the testing procedure on the HBM PHY; or the MBIST is coupled with the die-to-die interface and configured to operate the testing procedure on the die-to-die interface.

11. The semiconductor device of claim 9, wherein the processor and the one or more additional memory dies are not coupled independently of the HBM device.

12. The semiconductor device of claim 9, wherein the HBM device returns data to the processor at a higher bandwidth than a bandwidth at which the one or more additional memory dies return data to the memory controller.

13. The semiconductor device of claim 9, wherein the MBIST is coupled with the one or more memory dies and the memory controller through control logic, wherein the control logic enables the MBIST to operate the testing procedure on the one or more memory dies in a first state and operate the testing procedure on the memory controller in a second state.

14. The semiconductor device of claim 9, wherein the one or more additional memory dies comprises one or more Low-Power Double Data Rate (LPDDR) 5 memory dies.

15. The semiconductor device of claim 9, wherein the die-to-die interface is compliant with a Universal Chiplet Interconnect Express (UCIe) standard.

16. The semiconductor device of claim 9, wherein:
the MBIST is coupled with the processor through the substrate;
the processor is configured to provide one or more testing sequences to the MBIST through the substrate; and
the one or more testing sequences are included within the testing procedure.

17. A method comprising:
initiating, by a memory built-in self-test (MBIST) engine on an interface die of a high- bandwidth memory (HBM) device, one or more first test sequences to test an HBM physical layer (PHY) configured to facilitate communication between a processor and one or more memory dies of the HBM device;
initiating, by the MBIST engine, one or more second test sequences to test a memory controller and a standard compliant PHY located on the interface die, the memory controller configured to communicate signaling to one or more additional memory dies separate from the HBM device, and the standard compliant PHY configured to facilitate communication between the processor and the memory controller; and
determining an operability of the HBM PHY, the memory controller, and the standard compliant PHY based on the one or more first test sequences and the one or more second test sequences.

18. The method of claim 17, further comprising:
configuring, by the MBIST engine, control logic at a data path between the MBIST engine and the memory controller, the HBM PHY, and the standard compliant PHY to be in a first state that directs signaling from the MBIST engine toward the HBM PHY, wherein the one or more first test sequences are initiated in response to configuring the control logic at the data path into the first state; and
configuring, by the MBIST engine, the control logic at the data path to be in a second state that directs signaling from the MBIST engine toward the memory controller and the standard compliant PHY,
Client Ref. Nos. 2023147814-US-2 wherein the one or more second test sequences are initiated in response to configuring the control logic at the data path into the second state.

19. The method of claim 17, further comprising:
receiving, at the MBIST engine and from the processor, one or more third test sequences to test at least one of: the HBM PHY, or the memory controller and the standard compliant PHY; and
in response to receiving the one or more third test sequences, initiating, by the MBIST engine, the one or more third test sequences to test the at least one of: the HBM PHY, or the memory controller and the standard compliant PHY.

20. The method of claim 17, wherein the memory controller is compliant with a Low-Power Double Data Rate (LPDDR) 5 standard.
